(19) United States
(12) Patent Application Publication
(10) Pub. No.: US 2018/0151766 A1
(43) Pub. Date: May 31, 2018

(54) ANTI-CORROSION PROTECTION IN PHOTOVOLTAIC STRUCTURES

(71) Applicant: SolarCity Corporation, San Mateo, CA (US)

(72) Inventors: Christoph G. Erben, Los Gatos, CA (US); Milan Padilla, Mountain View, CA (US); Zhi-Wen Sun, Sunnyvale, CA (US)

(73) Assignee: SolarCity Corporation, San Mateo, CA (US)

(21) Appl. No.: 15/363,901

(22) Filed: Nov. 29, 2016

(51) Int. Cl. H01L 31/048; H01L 31/02; H01L 31/0747; H01L 31/0224; H01L 31/18

(52) U.S. Cl. CPC H01L 31/0481; H01L 31/0488; H01L 31/1876; H01L 31/0747; H01L 31/022466; H01L 31/0201

(57) ABSTRACT

A system for fabricating a photovoltaic module is provided. During operation, the system can obtain a plurality of photovoltaic structures. A respective photovoltaic structure can include first and second metallic grids on first and second surfaces, respectively. The system can then encapsulates the photovoltaic structures between a first cover and a second cover using an encapsulant having a moisture vapor transmission rate (MVTR) less than a predetermined value, thereby preventing oxidation and corrosion of the metallic grids during the service life of the photovoltaic module.

### FIELD OF THE INVENTION

This generally relates to the fabrication of photovoltaic structures. More specifically, this is related to the fabrication of the electrical contact for photovoltaic structures.

### Definitions

“Solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

“Finger lines,” “finger electrodes,” and “fingers” refer to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or solar cell strip. A photovoltaic structure is not limited to a device fabricated by a particular method. For example, a photovoltaic structure can be a crystalline silicon-based solar cell, a thin film solar cell, an amorphous silicon-based solar cell, a polycrystalline silicon-based solar cell, or a strip thereof.

### BACKGROUND

Advances in photovoltaic technology, which is used to make solar panels, have helped solar energy gain mass appeal among those wishing to reduce their carbon footprint and decrease their monthly energy costs. Solar cells that include electrodes made of electroplated Cu have been shown to improve the efficiency of the solar cells. However, Cu grids can be prone to oxidation and corrosion. Protecting the surface of the Cu grid lines using a corrosion-resistant material can be important in maintaining the efficiency of the solar cells during their service life.

In conventional fabrication facilities, the surface of the Cu grids can be coated with a layer of Sn using an immersion technique. However, the chemical displacement reaction occurring during the immersion process can lead to undercut of the Cu grids, which can lead to peeling of the Cu lines. Moreover, the chemical solution used in the immersion Sn process can include thiourea or its derivatives, which can be hazardous to the environment. Carefully designed waste treatment is often needed for proper disposal of the thiourea-containing solution and, thus, can significantly increase the solar cell manufacturing cost.

### SUMMARY

One embodiment can provide a system for fabricating a photovoltaic module. During operation, the system can obtain a plurality of photovoltaic structures. A respective photovoltaic structure can include first and second metallic grids on first and second surfaces, respectively. The system can then encapsulates the photovoltaic structures between a first cover and a second cover using an encapsulant having a moisture vapor transmission rate (MVTR) less than a predetermined value, thereby preventing oxidation and corrosion of the metallic grids during the service life of the photovoltaic module.

In a variation of this embodiment, the system can apply an organic coating over the photovoltaic structures such that exposed metallic surfaces of the first and second metallic grids are covered by the organic coating.

In a further variation, the organic coating can include one or more of: imidazole, derivatives of imidazole, and benzotriazole.

In a further variation, a thickness of the organic coating can be between 1 and 10 nm.

In a variation of this embodiment, the system can place the obtained photovoltaic structures within a non-corrosive environment prior to encapsulating the photovoltaic structures.

In a further variation, the non-corrosive environment can include an air-tight container that is filled with nitrogen or an inert gas, or is under vacuum.

In a variation of this embodiment, the moisture vapor transmission rate of the encapsulant can be less than 10 g/m²/day.

In a variation of this embodiment, the encapsulant can include one or more materials selected from a group consisting of: polyolefin, ionomer, and silicone.

In a variation of this embodiment, the first metallic grid can include a first edge busbar, and the second metallic grid can include a second edge busbar. The first and second edge busbars are positioned on opposite edges and opposite surfaces of the photovoltaic structure.

In a further variation, the system can further arrange the photovoltaic structured in such a way that the first edge busbar of a first photovoltaic structure overlaps with the second edge busbar of an adjacent photovoltaic structure, and apply conductive paste between the first and second edge busbars.

### BRIEF DESCRIPTION OF THE FIGURES

FIG. 1 shows an exemplary photovoltaic structure.

FIG. 2 shows an exemplary process of fabricating a photovoltaic structure, according to one embodiment.

FIG. 3A shows an exemplary grid pattern on the front surface of a photovoltaic structure.

FIG. 3B shows an exemplary grid pattern on the back surface of a photovoltaic structure.

FIG. 4A shows a string of cascaded strips.

FIG. 4B shows a side view of the string of cascaded strips.

FIG. 5 shows an exemplary process for fabricating a solar panel, according to one embodiment.

FIG. 6 shows an exemplary process for fabricating a solar panel, according to one embodiment.

FIG. 7 shows an exemplary solar panel, according to one embodiment.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention can provide a low-cost and environmentally friendly solution for preventing corrosion of metallic contacts on photovoltaic structures. In order to reduce corrosion and oxidation of the metallic contacts of photovoltaic structures within a solar panel, materials with low moisture vapor transmission rate (MVTR) (e.g., polyolefin, ionomer, silicone, etc.) can be used as encapsulant. In addition to the low-MVTR, these encapsulation materials themselves have very low water content and do not release corrosive gases (such as acetic acid). This anti-corrosion solution is low cost, because the low-MVTP encapsulant can be compatible with or be part of standard module manufacturing practices. To preserve the integrity of the metallic grids before the photovoltaic structures are laminated between the encapsulation layers, a thin layer of organic coating can be applied over the grids, preventing the metallic surfaces from exposure to oxygen and moisture. This thin coating can evaporate during the module manufacturing process and, hence, does not interfere with the adhesion and electrical conduction between busbars.

Photovoltaic Structures with Electroplated Metallic Grids

Electroplated metallic electrode grids (e.g., electroplated Cu grids) have been shown to exhibit lower resistance than conventional aluminum or screen-printed-silver-paste electrodes. Such low electrical resistance can be essential in achieving high-efficiency photovoltaic structures. In addition, electroplated copper electrodes can also tolerate microcracks better, which may occur during a subsequent cleaving process. Such microcracks might impair silver-paste-electrode cells. Plated-copper electrode, in contrast, can preserve the conductivity across the cell surface even if there are microcracks. The copper electrode's higher tolerance for microcracks allows the use of thinner silicon wafers, which can reduce the overall fabrication cost. More details on using copper plating to form low-resistance electrodes on a photovoltaic structure are provided in U.S. patent application Ser. No. 13/220,532, Attorney Docket No. P59-1NUS, entitled “SOLAR CELL WITH ELECTROPLATED GRID,” filed on Aug. 29, 2011, the disclosure of which is incorporated herein by reference in its entirety.

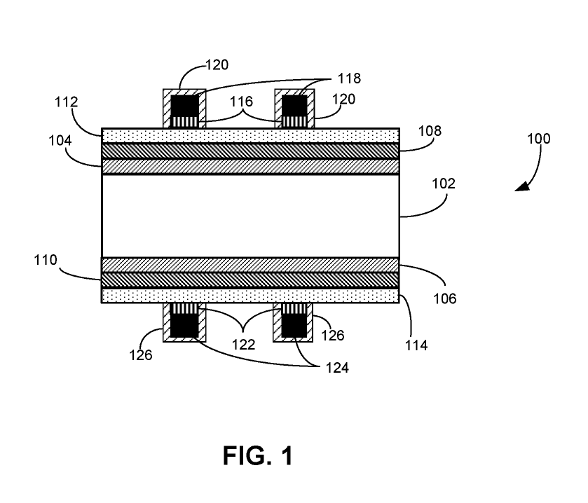

FIG. 1 shows an exemplary photovoltaic structure. In FIG. 1, photovoltaic structure 100 can include base layer 102, front and back passivation layers 104 and 106, surface-field layer 108, emitter layer 110, front and back TCO layers 112 and 114, a front electrode grid that can include Cu seed layer 116, electroplated bulk Cu layer 118, and metallic protection layer 120, and a back electrode grid that can include Cu seed layer 122, electroplated bulk Cu layer 124, and metallic protection layer 126.

Base layer 102 can include various materials, such as undoped or lightly doped monocrystalline silicon and undoped or lightly doped microcrystalline silicon. Passivation layers 104 and 106 can include various dielectric materials, such as silicon oxide (SiOₓ) hydrogenated SiOₓ, silicon nitride (SiNₓ), hydrogenated SiNₓ, aluminum oxide (AlOₓ), silicon oxynitride (SiON), hydrogenated SiON, and any combination thereof. In addition to dielectric material, the passivation layers may also include intrinsic (e.g., undoped) silicon in various forms, such as single crystalline Si, polycrystalline Si, amorphous Si, and any combination thereof. The passivation layers can be formed using a wet process, such as wet or steam oxidation, or a chemical-vapor-deposition (CVD) process. Emitter layer 110 can include heavily doped wide bandgap material, such as amorphous Si (a-Si) or hydrogenated a-Si (a-Si:H). If base layer 102 is lightly doped, emitter layer 110 can have a conductive doping type opposite to that of base layer 102. Surface-field layer 108 can also include heavily doped wide bandgap material, such as a-Si or a-Si:H. The conductive doping type of surface-field layer 108 can be opposite to that of emitter layer 110. In some embodiments, emitter layer 110 and/or surface-field layer 108 can have a graded doping profile, with a lower doping concentration near the base/emitter or base/surface-field layer interface. The formation of emitter layer 110 and/or surface-field layer 108 can involve a CVD process, such as a plasma-enhanced chemical-vapor-deposition (PECVD) process. In the example shown in FIG. 1, emitter layer 110 is positioned on the back side of the photovoltaic structure, facing away from the incident light. In practice, the emitter can also be placed on the front side of the photovoltaic structure, facing the incident light.

Front and back TCO layers 112 and 114 can be formed using materials such as indium-tin-oxide (ITO), aluminum-doped zinc-oxide (ZnO:Al), gallium-doped zinc-oxide (ZnO:Ga), tungsten-doped indium oxide (IWO), Zn-in-Sn—O (ZITO), Ti-doped indium oxide, Ta-doped indium oxide, and their combinations. The TCO layers can be formed using a low-temperature PVD process. For example, the TCO layers can be formed by sputtering without intentional heating of the substrate. The TCO layers can be subsequently annealed to improve their electro-optical properties (e.g., high transparency over a wide wavelength range and low electrical resistivity).

As discussed in the aforementioned U.S. patent application Ser. No. 13/220,532, a thin metallic seed layer (e.g., Cu seed layer 116) can be deposited to improve the adhesion between the electroplated Cu grid and the underlying TCO layer using a PVD technique (e.g., sputtering or evaporation), on top of the TCO layer, because high-energy atoms sputtered from the target can adhere well to the TCO layer. This metallic seed layer can then enhance the adhesion between the TCO layer and the subsequently plated Cu grid. The thickness of the metallic seed layer can be between 20 and 500 nm.

The main body of the electrode grid (e.g., bulk Cu layers 118 and 124) can be formed using an electroplating process. As discussed previously, electroplated Cu grids can provide lower resistance and be more tolerable of microcracks. However, Cu grids can be subject to oxidation and corrosion if exposed to air. To protect the Cu grids against negative environmental factors during the service life of the photovoltaic structure, a metallic protection layer can be formed to cover the sidewalls and top surface of the Cu grids, preventing exposure of the Cu grids to the environment. For example, as shown in FIG. 1, metallic protection layer 120 is covering the sidewalls of Cu layers 116 and 118 and the top surface of Cu bulk layer 118; similarly, metallic protection layer 126 is covering the sidewalls of Cu layers 122 and 124 and the top surface of Cu bulk layer 124.

Metallic protection layers 120 and 126 can include metallic materials that can resist oxidation and corrosion and provide solderability. More specifically, Sn, Ag, or Sn/Ag alloy can often be used to form the metallic protection layers. In order to cover the sidewalls of the Cu grids, an immersion plating technique (e.g., immersion tin) can be used to form the metallic protection layers. For example, metallic protection layers 120 and 126 can include a Sn layer that is 0.3-1.0 um thick, and the Sn layer can be formed by immersing the photovoltaic structure in a solution that includes Sn ions, such that a displacement reaction can occur between the Sn ions and the Cu grids.

Because the redox potential of Cu is higher than Sn, to enable the displacement reaction, a complexing agent, such as thiourea (SC(NH₂)₂) or its derivatives, is needed to reduce the redox potential of the Cu. However, thiourea is a hazardous material and often requires carefully designed waste treatment for safe disposal. Treating thiourea waste can be expensive, thus significantly increasing the fabrication cost of the photovoltaic structures. To reduce fabrication cost and mitigate the negative effect on the environment, some approaches use an environmentally friendly organic compound (e.g., imidazole or its derivatives (e.g., polybenzimidazole), and benzotriazole) to coat the metallic grids. This organic coating can isolate the Cu grid lines, including the finger lines and busbars, from the environment, reducing Cu oxidation and corrosion. However, the organic coating solution has its own shortcomings. More specifically, applying the organic coating can add manufacturing complexity and the coating can sometimes cause mechanical or electrical failure.

To overcome the problems facing the immersion plating and organic coating technologies, in some embodiments of the present invention, a special encapsulation material can be used during panel fabrication to protect the metallic grid from oxidation and corrosion. Such material would have low water content, low moisture vapor transmission rate (MVTR), and great adhesion properties. In addition to the above properties, this special encapsulant needs to be non-corrosive and compatible with standard module manufacturing practices while providing a conformal coating onto the metallic grid. In some embodiments, the special encapsulant can include polymer blend material from chemical class of polyolefin, ionomer, and silicone. The MVTR of the encapsulant can be less than a predetermined threshold value, such as less than 10 g/m²/day, preferably less than 5 g/m²/day.

Note that the low-MVTR encapsulant can also be used during the panel lamination process to encapsulate the Si-based photovoltaic structures within the front and back covers of a solar panel. Hence, protecting the Cu grids by using the low-MVTR encapsulant does not add fabrication cost. Moreover, because the low-MVTR encapsulant within the panel can effectively block the ingress of moistures during the service life of the panel, there is no longer a need for immersion plating of a metallic protective layer over the Cu grids, thus making the panel fabrication more environmental friendly. It should be noted the special encapsulant can be used as the only corrosion protection measure or used in conjunction with other solutions, for example the organic coating solution discussed above, to provide sufficient corrosion protection.

Although the low-MVTR encapsulant can ensure that the Cu grids are protected against moisture and oxygen after the photovoltaic structures are encapsulated between the solar panel covers, the Cu grids may be exposed to oxygen and moisture before the encapsulation operation. In a conventional manufacture facility, after the photovoltaic structures have been fabricated, either individually or in batches, they may be temporarily stored on open shelves before subsequent manufacturing operations, such as assembling of a panel. Depending on the size and throughput of the facility, the photovoltaic structures may stay on the open shelves for hours, days, or weeks. This can lead to oxidation and corrosion of the Cu grids, because the Cu grids can be exposed to oxygen and moisture that exist in the large environment of the manufacture facility.

To overcome this problem, in some embodiments, after the formation of the Cu grids, photovoltaic structures can be placed into a non-corrosive environment before the low-MVTR encapsulant is applied. For example, the photovoltaic structures can be placed inside an airtight container (e.g., a cart, a cabinet, a pod, a room, etc.) that is filled with nitrogen or inert gases. In some embodiments, the airtight container can be filled with purified N₂ with a purity of at least 99.9%, preferably around 99.95%. The pressure of nitrogen within the carts/cabinets can be maintained at 700-800 Torr, preferably at 760-770 Torr. Alternatively, the airtight container can be kept under vacuum. Regardless of whether the container is under vacuum or filled with non-reactive gases, the moisture and oxygen levels in the container need to be carefully controlled to prevent corrosion of the Cu grids. For example, the oxygen level can be maintained at below 300 ppm, and the moisture (H₂O vapor) level can be maintained at below 1000 ppm, preferably below 100 ppm.

Another approach to prevent corrosion of the Cu grids before the panel formation is to apply a very thin layer of organic coating over the surface of the Cu grids. In some embodiments, immediate after the formation of the Cu grids, photovoltaic structures can be dipped or submerged into a solution that contains organic corrosion inhibitors, resulting in a thin layer of the organic corrosion inhibitors being coated on the surfaces of the Cu grid. Examples of the organic corrosion inhibitors include, but are not limited to: imidazole or its derivatives (e.g., polybenzimidazole), and benzotriazole. In some embodiments, the thickness of the organic coating can be carefully controlled (e.g., by controlling the dipping time) to be between 1 and 10 nm.

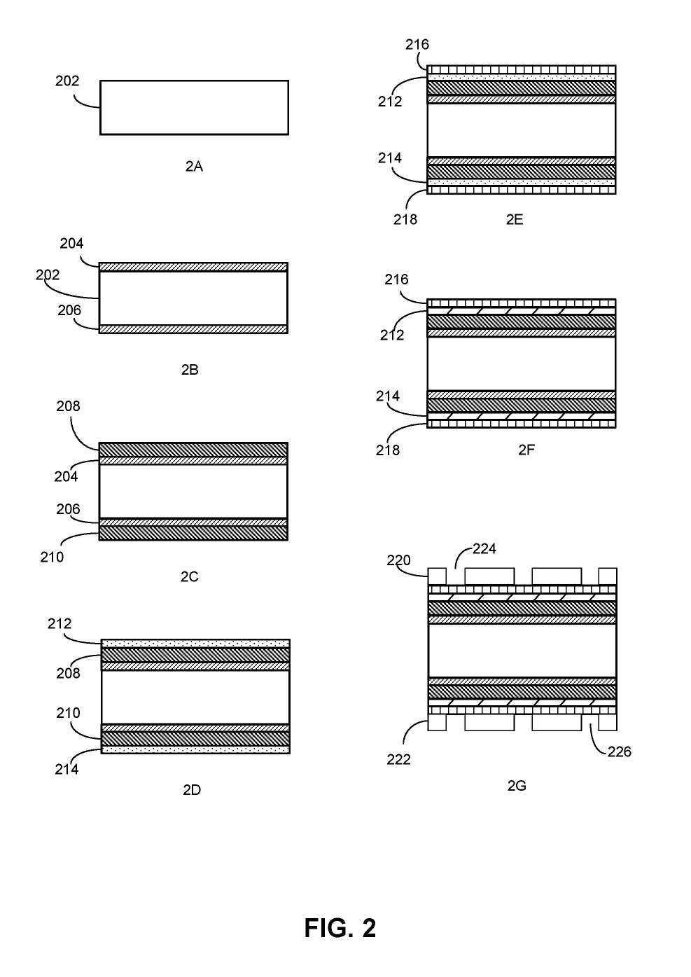

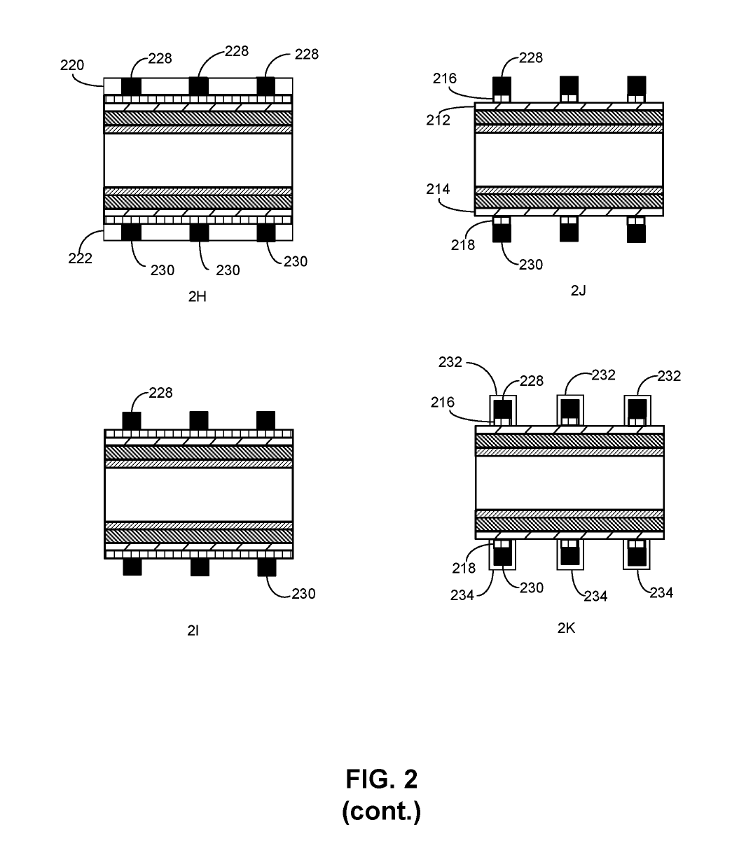

FIG. 2 shows an exemplary process of fabricating a photovoltaic structure, according to one embodiment. In operation 2A, substrate 202 can be prepared. Substrate 202 can include a crystalline-Si (c-Si) wafer (e.g., a monocrystalline or polycrystalline silicon wafer). In some embodiments, preparing c-Si substrate 202 can include standard saw-damage etching (which removes the damaged outer layer of Si substrate 202) and surface texturing. The c-Si substrate 202 can be lightly doped with either n-type or p-type dopants. In one embodiment, c-Si substrate 202 can be lightly doped with n-type dopants (e.g., phosphorus). In addition to c-Si, other materials (such as metallurgical-Si) can also be used to form substrate 202.

In operation 2B, front and back passivation layers 204 and 206 can be formed on the front and back surfaces, respectively, of substrate 202. The passivation layers can also function as quantum-tunneling barrier (QTB) layers. In some embodiments, forming passivation layers 204 and 206 can involve a wet oxidation process or a CVD process. The thickness of passivation layers 204 and 206 can be between 1 and 50 angstroms.

In operation 2C, heavily doped surface-field layer 208 and emitter layer 210 can be formed on passivation layers 204 and 206, respectively, using one or more CVD processes. In some embodiments, both surface-field layer 208 and emitter layer 210 can include hydrogenated a-Si with a graded-doping profile. For n-type doped substrate 202, surface-field layer 208 can be doped with n-type dopants (e.g., phosphorus), and emitter layer 210 can be doped with p-type dopants (e.g., boron). The thickness of surface-field layer 208 and/or emitter layer 210 can be between 2 and 50 nm.

In operation 2D, TCO layers 212 and 214 can be formed on surface-field layer 208 and emitter layer 210, respectively. Forming TCO layers 212 and 214 can involve a PVD process, such as sputtering. In some embodiments, to prevent damage to the surface of surface-field layer 208 and emitter layer 210, TCO layers 212 and 214 can be formed using a low-temperature sputtering process, which can be performed without intentional heating of the substrate or with active cooling of the substrate. More specifically, during sputtering, the temperature of the substrate is maintained below 130° C., preferably below 80° C. In some embodiments, H₂ and water vapor can also be injected into the PVD chamber to improve the film quality of TCO layers 212 and 214.

In some embodiments, TCO layers 212 and 214 can include indium oxide (In₂O₃) doped with Ti and Ta, which can provide superior electro-optical properties after annealing. The combined doping of Ti and Ta can be less than 2% by weight. Other types of TCO materials can also be possible, including but not limited to: ITO with low (e.g., less than 2% by weight) SnO₂ doping, tungsten-doped In₂O₃ (IWO), and cerium-doped indium oxide (ICeO).

In operation 2E, metallic seed layers 216 and 218 can be formed on TCO layers 212 and 214, respectively. Forming the metallic seed layers can also involve a PVD process. In some embodiments, metallic seed layers 216 and 218 can be formed using the same PVD tool that forms TCO layers 212 and 214 without disrupting the vacuum, meaning that the photovoltaic structures remain in the same vacuum environment during the deposition of all these layers. This can significantly reduce the processing time, because there is no need to pump down the PVD chamber or chambers between processes.

In operation 2F, the photovoltaic structures can be sent to an annealing oven for annealing of the TCO layers and the metallic seed layers. The annealing temperature can be set at a temperature between 200 and 230° C. and the annealing dwell time can be between 20 and 40 minutes. After the thermal annealing process, TCO layers 212 and 214 can transition from an amorphous state to a multicrystalline state with improved electro-optical properties.

In operation 2G, dry-film resist layers 220 and 222 can be laminated and patterned on metallic seed layers 216 and 218, respectively. The patterned dry-film resist layers can define the locations of the grid lines. Standard photoresist patterning processes, including exposure and development, can be used to pattern dry-film resist layers 220 and 222. Windows (e.g., windows 224 and 226) within the photoresist layers correspond to locations of the grid lines.

In operation 2H, metallic material can be deposited into windows within the photoresist layers to form metallic bulk layers 228 and 230. In some embodiments, an electroplating process can be used to deposit metallic material (e.g., Cu). More specifically, the photovoltaic structure can be submerged in an electrolyte bath containing metallic ions (e.g., Cu ions). Because the photoresist is electrically insulated, the metallic ions can only be deposited into the windows, which expose the electrically conductive metallic seed layers, within dry-film resist layers 220 and 222. The thickness of metallic bulk layers 228 and 230 can be between 10 and 200 μm. In an alternative embodiment, an additional metallic corrosion-resistant protection layer (now shown in FIG. 2) can be formed on top of metallic bulk layers 228 and 230. More specifically, a plating technique (e.g., electroplating or electroless plating) can be used to plate a Sn layer on top of metallic bulk layers 228 and 230. The plated Sn layer can protect the top surface of the metallic layers from oxidation and corrosion, and can facilitate subsequent, if any, soldering on the busbars. In addition to Sn, Ag or a Sn/Ag alloy can also be used to form the corrosion-resistant protection layer.

In operation 2I, dry-film resist layers 220 and 222 can be stripped off. In operation 2J, metallic seed layers 216 and 218 can be partially etched, using bulk layers 228 and 230 as masks, to expose underlying TCO layers 212 and 214, respectively. Metallic seed layer 216 and bulk layer 228 together form the front side metallic grid, and metallic seed layer 218 and bulk layer 230 together form the back side metallic grid.

In operation 2K, the photovoltaic structure can be immersed in an aqueous solution of an organic compound (e.g., imidazole or its derivatives, and benzotriazole), resulting in organic coatings 232 and 234 being deposited over the top surface and sidewalls of the front and back metallic grids. The organic compound within the solution is selected such that it reacts only with Cu, forming a protective coating on the Cu surface without coating the TCO layers. Organic coating 232 can cover the exposed surfaces, including the top surface and sidewalls, of Cu bulk layers 228 and seed layer 216. Similarly, organic coating 234 can cover the top surface and sidewalls of Cu bulk layer 230 and seed layer 218. In some embodiments, the thickness of organic coating layers 232 and 234 can be carefully controlled. More specifically, organic coating layers 232 and 234 need to be thin enough (e.g., between 1 and 10 nm) such that they will evaporate during subsequent module manufacturing process and does not interfere with the adhesion and electrical conduction between busbars.

The organic coating over the surface of the Cu grids can prevent the Cu grids from exposure to the environment and, hence, can extend the shelf life of the fabricated photovoltaic structures by preserving the solderability of the Cu grids.

### Module Fabrication

As described in U.S. patent application Ser. No. 14/563,867, a solar panel can have multiple (e.g., three) strings, each string including cascaded strips, connected in parallel. Such a multiple-parallel-string panel configuration provides the same output voltage with a reduced internal resistance. In general, a cell can be divided into n strips, and a panel can contain n strings. Each string can have the same number of strips as the number of regular photovoltaic structures in a conventional single-string panel. Such a configuration can ensure that each string outputs approximately the same voltage as a conventional panel. The n strings can then be connected in parallel to form a panel. As a result, the panel's voltage output can be the same as that of the conventional single-string panel; while the panel's total internal resistance can be 1/n of the resistance of a string. Therefore, in general, a greater n can lead to a lower total internal resistance and, hence, more power extracted from the panel. However, a tradeoff is that as n increases, the number of connections required to interconnect the strings also increases, which increases the amount of contact resistance. Also, the greater n is, the more strips a single cell needs to be divided into, which increases the associated production cost and decreases overall reliability due to the larger number of strips used in a single panel.

Another consideration in determining n is the contact resistance between the electrode and the photovoltaic structure on which the electrode is formed. The greater this contact resistance, the greater n might need to be to effectively reduce the panel's overall internal resistance. Therefore, the type of electrode can dictate the number of strips. For example, conventional silver-paste or aluminum-based electrodes typically cannot produce ideal resistance between the electrode and underlying photovoltaic structure. As a result, such electrodes may require n to be greater than four. In some embodiments of the present invention, the electrodes, including both the busbars and finger lines, can be fabricated using a combination of physical vapor deposition (PVD) and electroplating of copper as an electrode material. The resulting copper electrode can exhibit lower resistance than an aluminum or screen-printed-silver-paste electrode. Consequently, a smaller n can be used to attain the benefit of reduced panel internal resistance. In some embodiments, n can be selected to be three, which is less than the n value generally needed for cells with silver-paste electrodes or other types of electrodes. Correspondingly, two grooves can be scribed on a single cell to allow the cell to be divided into three strips.

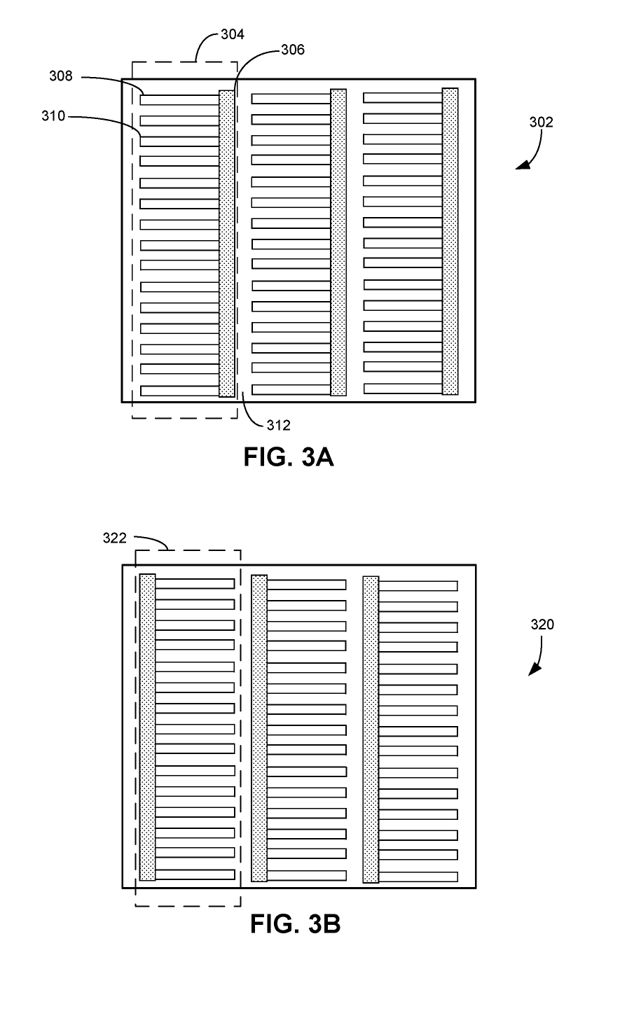

FIG. 3A shows an exemplary grid pattern on the front surface of a photovoltaic structure. In the example shown in FIG. 3A, grid 302 can include three sub-grids, such as sub-grid 304. This three sub-grid configuration can allow the photovoltaic structure to be divided into three strips. To enable cascading, each sub-grid can have an edge busbar, which can be located either at or near the edge. In the example shown in FIG. 3A, each sub-grid can include an edge busbar (“edge” here refers to the edge of a respective strip) running along the longer edge of the corresponding strip and a plurality of parallel finger lines running in a direction parallel to the shorter edge of the strip. For example, sub-grid 304 can include edge busbar 306, and a plurality of finger lines, such as finger lines 308 and 310. To facilitate the subsequent laser-assisted scribe-and-cleave process, a predefined blank space (i.e., space not covered by electrodes) can be inserted between the adjacent sub-grids. For example, blank space 312 can be defined to separate sub-grid 304 from its adjacent sub-grid. In some embodiments, the width of the blank space, such as blank space 312, can be between 0.1 mm and 5 mm, preferably between 0.5 mm and 2 mm. There is a tradeoff between a wider space that leads to a more tolerant scribing operation and a narrower space that leads to more effective current collection. In a further embodiment, the width of such a blank space can be approximately 1 mm.

FIG. 3B shows an exemplary grid pattern on the back surface of a photovoltaic structure. When showing the back surface, for illustration purposes, the photovoltaic structure is assumed to be transparent. The grid patterns on the front and back surfaces of the photovoltaic structure are viewed from the same viewing point. In the example shown in FIG. 3B, back grid 320 can include three sub-grids, such as sub-grid 322. To enable cascaded and bifacial operation, the back sub-grid may correspond to the front sub-grid. More specifically, the back edge busbar can be located at the opposite edge of the front side edge busbar. In the examples shown in FIGS. 3A and 3B, the front and back sub-grids can have similar patterns except that the front and back edge busbars are located adjacent to opposite edges of the strip. In addition, locations of the blank spaces in back conductive grid 320 can correspond to locations of the blank spaces in front conductive grid 302, such that the grid lines do not interfere with the subsequent scribe-and-cleave process. In practice, the finger line patterns on the front and back sides of the photovoltaic structure may be the same or different.

In the examples shown in FIGS. 3A and 3B, the finger line patterns can include continuous, non-broken loops. For example, as shown in FIG. 3A, finger lines 308 and 310 can both include connected loops. This type of “looped” finger line pattern can reduce the likelihood of the finger lines peeling away from the photovoltaic structure after long use. Optionally, the sections where parallel lines are joined can be wider than the rest of the finger lines to provide more durability and prevent peeling. Patterns other than the one shown in FIGS. 3A and 3B, such as un-looped straight lines or loops with different shapes, are also possible.

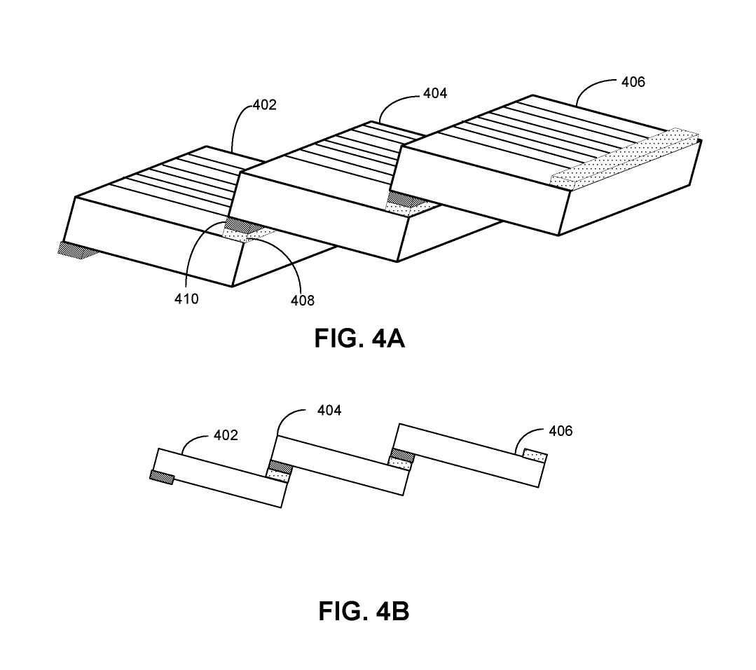

To form a cascaded string, cells or strips (e.g., as a result of a scribing-and-cleaving process applied to a regular square cell) can be cascaded with their edges overlapped. FIG. 4A shows a string of cascaded strips. In FIG. 4A, strips 402, 404, and 406 can be stacked in such a way that strip 406 can partially overlap adjacent strip 404, which can also partially overlap (on an opposite edge) strip 402. Such a string of strips can form a pattern that is similar to roof shingles. Each strip can include top and bottom edge busbars located at opposite edges of the top and bottom surfaces, respectively. Strips 402 and 404 may be coupled to each other via an edge busbar 408 located at the top surface of strip 402 and an edge busbar 410 located at the bottom surface of strip 404. To establish electrical coupling, strips 402 and 404 can be placed in such a way that bottom edge busbar 410 is placed on top of and in direct contact with top edge busbar 408.

FIG. 4B shows a side view of the string of cascaded strips. In the example shown in FIGS. 4A and 4B, the strips can be part of a 6-inch square photovoltaic structure, with each strip having a dimension of approximately 2 inches by 6 inches. To reduce shading, the overlapping between adjacent strips should be kept as small as possible. In some embodiments, the single busbars (both at the top and the bottom surfaces) can be placed at the very edge of the strip (as shown in FIGS. 4A and 4B). The same cascaded pattern can extend along an entire row of strips to form a serially connected string.

When forming a solar panel, adjacent strips may be bonded together via edge busbars. Such bonding can be important to ensure that the electrical connections are well maintained when the solar panel is put into service. One option for bonding the metallic busbars can include soldering. For example, the plated Sn on the top surface of busbars can facilitate soldering between the overlapping busbars. More specifically, heat and pressure used in the subsequent lamination process can solder together the edge busbars that are in contact, such as edge busbars 408 and 410. However, the rigid bonding between the soldered contacts may lead to cracking of the thin strips. Moreover, when in service solar panels often experience many temperature cycles, and the thermal mismatch between the metal and the semiconductor may create structural stress that can lead to fracturing.

To reduce the thermal or mechanical stress, it can be preferable to use a bonding mechanism that is sufficiently flexible and can withstand many temperature cycles. One way to do so is to bond the strips using flexible adhesive that is electrically conductive. For example, adhesive (or paste) can be applied on the surface of top edge busbar 408 of strip 402 (shown in FIG. 4A). When strip 404 is placed to partially overlap with strip 402, bottom edge busbar 410 can be bonded to top edge busbar 408 by the adhesive, which can be cured at an elevated temperature. Different types of conductive adhesive or paste can be used to bond the busbars. In one embodiment, the conductive paste can include a conductive metallic core surrounded by a resin. When the paste is applied to a busbar, the metallic core establishes an electrical connection with the busbar while the resin that surrounds the metallic core functions as an adhesive. In another embodiment, the conductive adhesive may be in the form of a resin that includes a number of suspended conductive particles, such as Ag or Cu particles. The conductive particles may be coated with a protective layer. When the paste is thermally cured, the protective layer can evaporate to enable electrical conductivity between the conductive particles suspended inside the resin. In some embodiments, the conductive paste may be in the form of a resin that includes material from the especial encapsulant that have great adhesive properties while providing additional corrosion protection layer in addition to the encapsulant that surrounds the soldered strip during the panel fabrication operation.

Although the conductive paste can provide high-quality bonding between metallic surfaces (e.g., Cu surfaces), it may not be able to provide sufficient bonding for busbars coated with the organic coating, because the conductive paste does not stick well to the organic coating. However, because the organic coatings are extremely thin (e.g., between 1 and 10 nm), when the conductive paste is cured under heat and pressure, the thin organic coatings will evaporate, resulting in the conductive paste coming into direct contact with the metallic surfaces to generate strong bond. In alternative embodiments, the busbars can be bare (e.g., without any coating or protective layer), and the conductive paste can be directly deposited onto the metallic surface of the busbars. Note that, in such situations, to prevent the bare busbars from corrosion, the photovoltaic structures should have been stored in a non-corrosive environment.

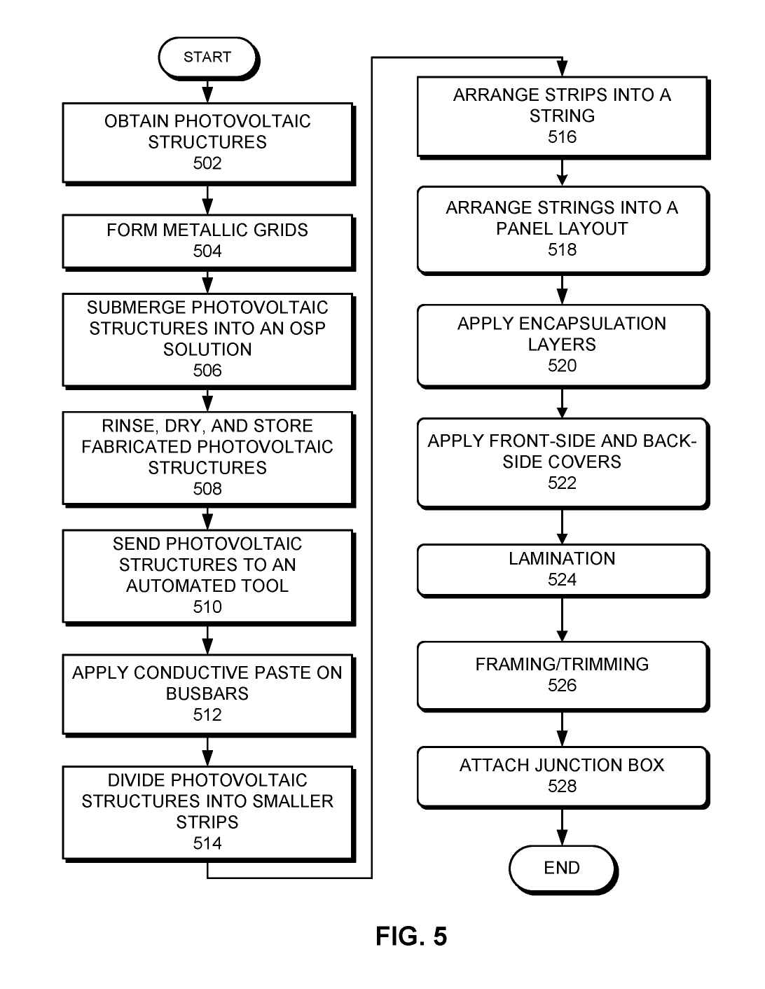

FIG. 5 shows an exemplary process for fabricating a solar panel, according to one embodiment. During fabrication, a number of photovoltaic structures can be obtained (operation 502). The photovoltaic structure can include the base, the emitter, and/or the surface-field layer. The photovoltaic structure can also optionally include a passivation layer on one or both sides of the base layer. The photovoltaic structure can include a TCO layer on one or both sides of the base layer. The TCO layer can be formed using a low temperature PVD process and can include Ti- and/or Ta-doped In₂O₃. Metallic grids can be formed on both sides of the photovoltaic structures (operation 504). Forming a metallic grid can involve depositing, using a PVD technique, a metallic seed layer (e.g., a Cu seed layer) on the TCO layer, and depositing, using a plating technique, a metallic bulk layer (e.g., an electroplated Cu layer) on the seed layer. In some embodiments, the metallic grid can also include a cap layer (e.g., a Sn layer), formed using a plating technique, on top of the metallic bulk layer. A thermal annealing process can also be performed to anneal the TCO layers and the metallic seed layers.

In some embodiments, the photovoltaic structures can be subsequently submerged into an organic solution, resulting in a thin layer of organic coating being formed on exposed Cu surfaces (operation 506). If the Cu grids do not have a Sn cap layer, the organic coating will be formed on the top surface and sidewalls of the Cu grids; otherwise, the organic coating will be formed only on the sidewalls of the Cu grids. The organic solution can include an aqueous solution of certain organic compounds. Examples of the organic compounds can include imidazole, polybenzimidazole, benzotriazole, etc. The thickness of the organic coating can be carefully controlled. In some embodiments, the thickness of the organic coating can be between 1 and 10 nm.

After the organic coating, the photovoltaic structures can be rinsed and dried, and temporarily stored before sent to an automated tool for the formation of a string or panel (operations 508 and 510). Because the exposed Cu surfaces have been coated with a thin layer of organic coating, the photovoltaic structures can be stored on open shelves for a prolonged time period (e.g., days or weeks), without risking oxidation and corrosion of the Cu grids. At the automated panel-formation tool, conductive paste can be applied onto the busbars (operation 512). More details about the applying the conductive-paste can be found in U.S. patent application Ser. No. 14/866,806, Attorney Docket No. P103-6NUS, entitled “METHODS AND SYSTEMS FOR PRECISION APPLICATION OF CONDUCTIVE ADHESIVE PASTE ON PHOTOVOLTAIC STRUCTURES,” filed on Sep. 25, 2015, the disclosure of which is incorporated herein by reference in its entirety.

Subsequently, the photovoltaic structures can be divided into smaller strips (operation 514). Dividing the photovoltaic structures can involve scribing and cleaving operations. In some embodiments, a laser-based scribe-and-cleave technique is used. More specifically, a high-power laser beam is used to scribe the surface of the photovoltaic cell at the desired locations to a predetermined depth (such as 20% of the total stack thickness), followed by applying appropriate force to cleave the scribed photovoltaic cell into multiple smaller cells or strips. Note that, in order to prevent damages to the emitter junction, it is desirable to apply the laser scribing at the photovoltaic cell surface corresponding to the surface field layer. For example, if the emitter junction is at the front surface of the photovoltaic cell, the laser scribing should be applied to the back surface of the photovoltaic cell. In alternative embodiments, the photovoltaic structures may first be divided into smaller strips before the conductive paste is applied onto the busbars.

Multiple strips can then be arranged into an edge-overlapped fashion to form a string (operation 516). More specifically, the edge busbar of a strip is overlapped with an opposite edge busbar of an adjacent strip. The conductive paste can be sandwiched between the overlapping busbars. Heat and pressure can be applied to the string to cure the conductive paste, and the thin organic coating over the metallic grids can evaporate during the curing of the conductive paste, resulting in the conductive paste being in direct contact with the metallic surface of the grids, providing reliable mechanical bonding and electrical coupling.

Subsequent to the formation of multiple strings of strips, the multiple photovoltaic strings are arranged into a panel layout (operation 518). In some embodiments, three U-shaped strings can be laid out next to each other to form a panel layout that includes 6 rows of strips. After laying out the strings, encapsulation layers can be applied (operation 520). More specifically, the strings can be sandwiched between two layers of low-MVTR encapsulant. As discussed previously, the low-MVTR encapsulant also has low water content and great adhesion properties so that the encapsulation layers can easily adhere to the photovoltaic structures (including metallic grids) and front and back covers. In some embodiments, the low-MVTR encapsulant can include polyolefin, ionomer, and silicone. Compared to conventionally used encapsulant in solar modules, such as ethyl-vinyl acetate (EVA), the low-MVTR encapsulant can effectively stop the ingress of moistures into the solar panel. Moreover, unlike EVA, the above mentioned low-MVTR encapsulant do not release acetic acid gases, which can be corrosive to Cu.

The front- and back-side covers can be applied over the encapsulant (operation 522), and the entire photovoltaic panel can go through the normal lamination process (operation 524). In some embodiments, the front-side cover can be made of glass, and the back-side cover can be made of glass, polyvinyl fluoride (PVF), or polyethylene terephthalate (PET). Note that, to ensure superior bifacial performance, the backside cover should be made of glass. The lamination process is then followed by framing and trimming (operation 526), and the attachment of a junction box (operation 528).

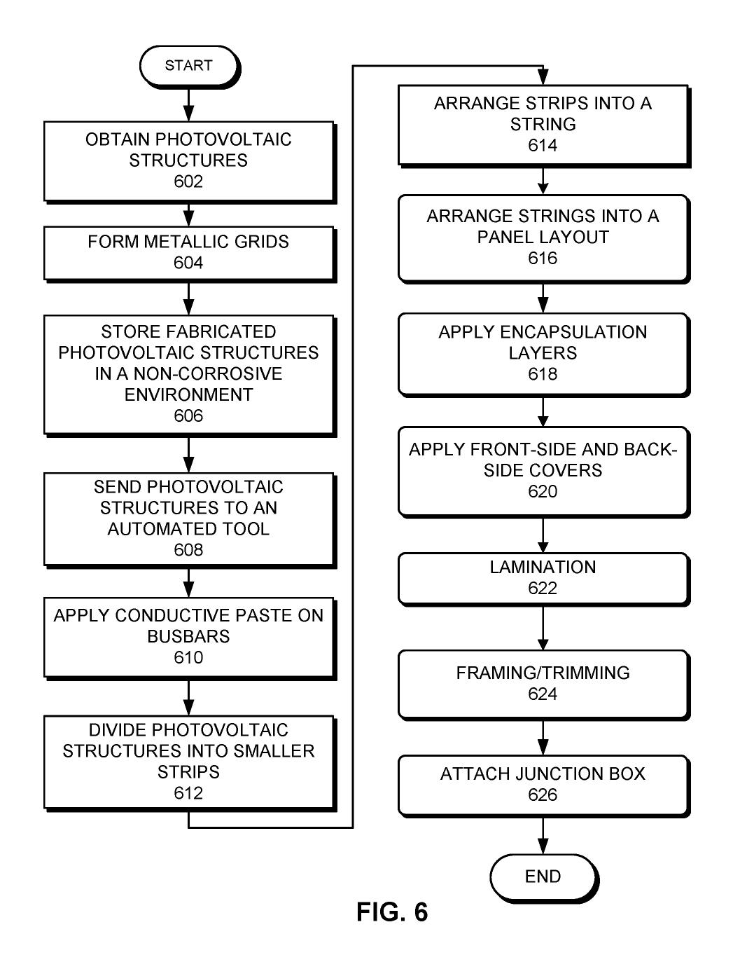

FIG. 6 shows an exemplary process for fabricating a solar panel, according to one embodiment. During fabrication, a number of photovoltaic structures can be obtained (operation 602), and metallic grids can be formed on the front and back surfaces of the photovoltaic structures (operation 604). Operations 602 and 604 can be similar to operations 502 and 504 shown in FIG. 5.

Subsequent to the formation of the metallic grids, without applying any protection coating, the photovoltaic structures can be stored inside a non-corrosive environment to wait for the next manufacturing step (operation 606). Examples of the non-corrosive environment can include an airtight container (e.g., a cart, a cabinet, a pod, a room, etc.) that is filled with nitrogen or inert gases, or kept under vacuum. The moisture and oxygen levels in the airtight container need to be carefully controlled to prevent corrosion of the metallic grids, such as Cu grids. In some embodiments, the oxygen level can be maintained at below 300 ppm, and the moisture (H₂O vapor) level can be maintained at below 1000 ppm, preferably below 100 ppm.

Subsequently, the photovoltaic structures can be taken out of the non-corrosive environment and sent to an automated panel-formation tool (operation 608). At the panel-formation tool, conductive paste can be applied onto the busbars (operation 610), and the photovoltaic structures can be divided into smaller strips (operation 612). In alternative embodiments, the photovoltaic structures may first be divided into smaller strips before the conductive paste is applied onto the busbars. The strips can then be arranged into strings (operation 614), and the strings can be laid out into a panel formation (operation 616). Low-MVTR encapsulant can then be applied onto the laid out strings (operation 618), and front- and back-side covers can also be applied (operation 620). The different layers of the panel, including the photovoltaic structures, the encapsulation layers, and the front- and back-side covers, can be laminated together under heat and pressure (operation 622). The lamination can be followed by framing and trimming (operation 624), and the attachment of a junction box (operation 626) to complete the panel formation. Operations 608-626 can be similar to operations 510-528 shown in FIG. 5.

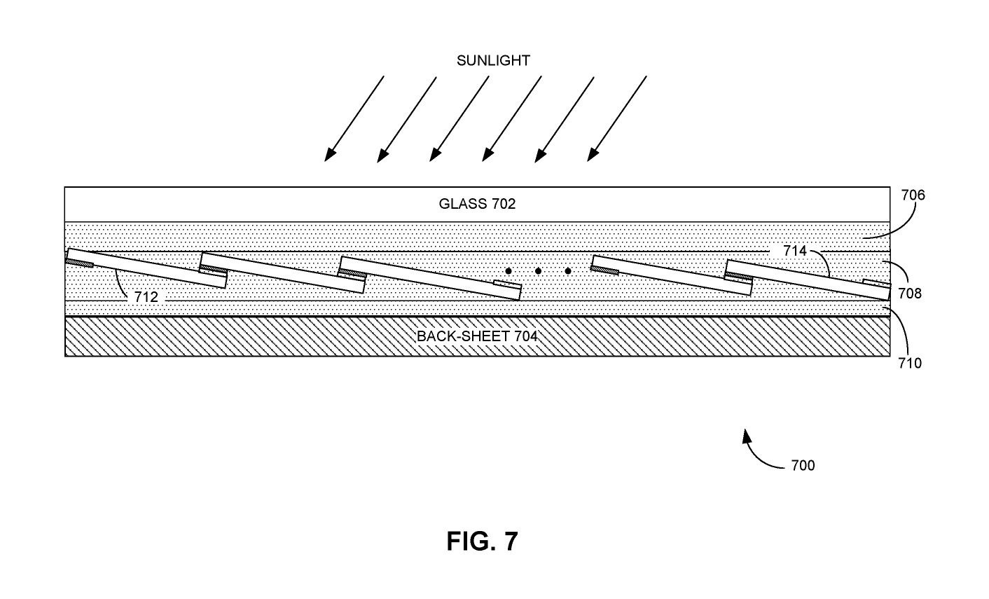

FIG. 7 shows an exemplary solar panel, according to one embodiment. Solar panel 700 can include glass cover 702, back-sheet 704, low-MVTR encapsulation layers 706, 708 and 710, and a plurality of photovoltaic structures (e.g., photovoltaic structures 712 and 714). In the example shown in FIG. 7, glass cover 702 faces the sunlight (as indicated by the arrows), and back-sheet 604 faces away from the sunlight. Back-sheet 704 can be made of transparent materials (e.g., glass) or non-transparent materials (e.g., PVF and PET). Note that if bifacial operation is desired, back-sheet 704 should be made of transparent materials.

Low-MVTR encapsulation layers 706, 706, and 708 can include one or more low-MVTR encapsulation materials, such as polyolefin, ionomer, and silicone. FIG. 7 shows multiple low-MVTR encapsulation layers (e.g., layers 706, 708, and 710) sandwiched between glass cover 702 and back-sheet 704. These low-MVTR encapsulation layers encompass the photovoltaic structures. In fact, the low-MVTR encapsulant can be used to fill in any empty spaces left between components when they are placed between glass cover 702 and back-sheet 704, thus effectively preventing the ingress of moistures into solar panel 700. During lamination, under heat and pressure, the low-MVTR encapsulant can bond glass cover 702, back-sheet 704, the photovoltaic structures, and other internal circuit components that are not shown in FIG. 7 together to form an encapsulated stack for solar panel 700. Other standard panel components, such as a metal outer frame and a junction box, are not shown in FIG. 7.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A solar panel, comprising:
a first cover;
a second cover;
one or more encapsulation layers positioned between the first and second covers; and
a plurality of photovoltaic structures embedded within the encapsulation layers, wherein the encapsulation layers include encapsulant having a moisture vapor transmission rate (MVTR) less than a predetermined value.

2. The solar panel of claim 1, wherein the moisture vapor transmission rate of the encapsulant is less than 10 g/m²/day.

3. The solar panel of claim 1, wherein the encapsulation layers include one or more materials selected from a group consisting of:
polyolefin, ionomer, and silicone.

4. The solar panel of claim 1, wherein a respective photovoltaic structure comprises:
a multiplayer structure;
a first metallic grid comprising a first edge busbar positioned on a first surface of the multilayer structure; and
a second metallic grid comprising a second edge busbar positioned on a second surface of the multilayer structure, wherein the first and second edge busbars are positioned on opposite edges and opposite sides of the photovoltaic structure.

5. The solar panel of claim 4, wherein the photovoltaic structures are arranged in such a way that the first edge busbar of a first photovoltaic structure overlaps with the second edge busbar of an adjacent photovoltaic structure, with conductive paste positioned between the first and second edge busbars.

6. The solar panel of claim 4, wherein the multilayer structure further comprises:
a base layer;
a surface-field layer positioned on a first side of the base layer;
an emitter layer positioned on a second side of the base layer;
a first transparent conductive oxide layer positioned on the surface-field layer; and
a second transparent conductive oxide layer positioned on the emitter layer.

7. The solar panel of claim 4, wherein a respective metallic grid includes:
a metallic seed layer formed on the transparent conductive oxide layer using a physical-vapor-deposition technique; and
a metallic bulk layer formed on the metallic seed layer using a plating technique.

8. The solar panel of claim 1, wherein a respective photovoltaic structure comprises one or more metallic grids, and wherein a respective metallic grid includes at least one metallic surface that is prone to corrosion when exposed to moisture.

9. The solar panel of claim 8, wherein the photovoltaic structures are embedded within the encapsulation layers such that the exposed metallic surface is substantially covered by the encapsulant, thereby preventing the corrosion-prone metallic surface from being exposed to moisture.

10. The photovoltaic module of claim 8, wherein the at least one metallic surface includes a Cu surface.

11. A method for fabricating a photovoltaic module, comprising:
obtaining a plurality of photovoltaic structures, wherein a respective photovoltaic structure comprises first and second metallic grids on first and second surfaces, respectively;
encapsulating the photovoltaic structures between a first cover and a second cover using an encapsulant;
wherein a moisture vapor transmission rate (MVTR) of the encapsulant is less than a predetermined value.

12. The method of claim 11, further comprising applying an organic coating over the photovoltaic structures such that exposed metallic surfaces of the first and second metallic grids are covered by the organic coating.

13. The method of claim 12, wherein the organic coating comprises one or more of: imidazole, derivatives of imidazole, and benzotriazole.

14. The method of claim 12, wherein a thickness of the organic coating is between 1 and 10 nm.

15. The method of claim 11, further comprising:
placing the obtained photovoltaic structures within a non-corrosive environment prior to encapsulating the photovoltaic structures.

16. The method of claim 15, wherein the non-corrosive environment includes an air-tight container that is filled with nitrogen or an inert gas, or is under vacuum.

17. The method of claim 11, wherein the moisture vapor transmission rate of the encapsulant is less than 10 g/m²/day.

18. The method of claim 11, wherein the encapsulant includes one or more materials selected from a group consisting of: polyolefin, ionomer, and silicone.

19. The method of claim 11, wherein the first metallic grid comprises a first edge busbar, and wherein the second metallic grid comprises a second edge busbar, and wherein the first and second edge busbars are positioned on opposite edges and opposite surfaces of the photovoltaic structure.

20. The method of claim 19, further comprising:
arranging the photovoltaic structured in such a way that the first edge busbar of a first photovoltaic structure overlaps with the second edge busbar of an adjacent photovoltaic structure; and
applying conductive paste between the first and second edge busbars.
